(19) United States
(12) Patent Application Publication
(10) Pub. No.: US 2021/0257287 A1
(43) Pub. Date: Aug. 19, 2021

(54) CHIP PACKAGE AND CIRCUIT BOARD THEREOF

(71) Applicant: CHIPBOND TECHNOLOGY CORPORATION, Hsinchu (TW)

(72) Inventors: Yu-Chen Ma, Kaohsiung City (TW); Hsin-Hao Huang, Kaohsiung City (TW); Wen-Fu Chou, Kaohsiung City (TW); Gwo-Shyan Sheu, Kaohsiung City (TW)

(21) Appl. No.: 16/986,415

(22) Filed: Aug. 6, 2020

(30) Foreign Application Priority Data
Feb. 17, 2020 (TW) 109201720

(51) Int. Cl. H01L 23/498; H01L 23/00

(52) U.S. Cl. CPC H01L 23/49838; H01L 24/16; H01L 24/17; H01L 2224/73204; H01L 2224/16225; H01L 2224/17152; H01L 24/73

(57) ABSTRACT

A chip package includes a circuit board, a chip and an underfill. The circuit board includes a substrate, first circuit lines and second circuit lines. Each of the first circuit lines includes an inner lead and a first line fragment that are disposed on a chip mounting area and an underfill covering area of the substrate, respectively. The second circuit lines are disposed on the chip mounting area and not located between the adjacent inner leads so as to form a wider space between the adjacent first line fragments. The wider space enables the underfill to flow to between the circuit board and the chip and prevents air bubbles from being embedded in the underfill filled between the circuit board and the chip.

### FIELD OF THE INVENTION

This invention relates to a chip package and circuit board, and more particularly to a chip package and circuit board having dummy leads on a chip mounting area.

### BACKGROUND OF THE INVENTION

Owing to miniaturization and multifunction of electronic products, chips and circuit boards used to carry the chips have to be miniaturized. However, underfill is not easy to flow when it is filled between the miniaturized chip and circuit board. The more dummy bumps the chip has, the more dummy leads the circuit board has for bonding the dummy bumps. The area of the miniaturized circuit board cannot be increased, as a result, the underfill is more difficult to flow to between the miniaturized chip and circuit board and air bubbles may be formed between the chip and circuit board.

When the dummy leads and dummy bumps are increased, the adjacent dummy leads or the adjacent dummy bumps may contact to one another during the thermal compressing process to become short circuit.

Additionally, if the number of the dummy leads is increased, bridge circuit between the adjacent leads cannot be detected instantly after forming the leads and only can be detected in electrical test after bonding the chip to the circuit board. Consequently, manufacture cost and product defect rate are increased.

### SUMMARY

One object of the present invention is to form a wider space between adjacent circuit lines located on an underfill covering area so as to allow an underfill to flow to between a chip and a circuit board rapidly and prevent air bubbles from being embedded between the chip and the circuit board. Otherwise, short circuit or bridge circuit between adjacent circuit lines or adjacent bumps is preventable in thermal compressing process or circuit forming process.

A circuit board of the present invention includes a substrate, a plurality of first circuit lines, a plurality of second circuit lines and a solder resist layer. A chip mounting area and an underfill covering area are defined on the substrate, and the underfill covering area is adjacent to the chip mounting are along a direction of a first axis. The first circuit lines are arranged on the substrate along a direction of a second axis intersecting with the first axis and each includes an inner lead and a first line fragment connected with each other. A first space having a first width exists between the first line fragment of the adjacent first circuit lines. The inner lead of each of the first circuit lines is disposed on the chip mounting area and configured to bond to a first bump of a chip. The first line fragment of each of the first circuit lines is disposed on the underfill covering area. The second circuit lines are disposed on the chip mounting area and not located between the inner lead of the adjacent first circuit lines. Each of the second circuit lines is configured to bond to a second bump of the chip and has a width less than or equal to the first width of the first space. The solder resist layer covers the substrate and exposes the chip mounting area, the underfill covering area, the inner lead and the first line fragment of each of the first circuit lines, the first space and the second circuit lines.

A chip package of the present invention includes a circuit board as mentioned above, a chip and an underfill. The chip is mounted on the chip mounting area and includes a plurality of first bumps and a plurality of second bumps. Each of the first bumps is bonded to the inner lead of each of the first circuit lines, and each of the second bumps is bonded to each of the second circuit lines. The underfill is filled between the substrate and the chip and covers the underfill covering area and the first line fragment of each of the first circuit lines.

Because the second circuit lines are located on the chip mounting area and not located between the adjacent inner leads, a wider space (the first space) exists between the adjacent first line fragments to prevent air bubbles from being embedded between the chip and the circuit board. Furthermore, the second circuit lines on the chip mounting area can prevent short circuit or bridge circuit between adjacent circuit lines or adjacent bumps during circuit forming process or thermal compressing process.

### DESCRIPTION OF THE DRAWINGS

FIG. 1 is a top view diagram illustrating a circuit board in accordance with a preferred embodiment of the present invention.

FIG. 2 is a partial enlarged diagram of FIG. 1.

FIG. 3 is a top view diagram illustrating a chip package in accordance with a preferred embodiment of the present invention.

FIG. 4 is a partial enlarged diagram of FIG. 3.

FIG. 5 is a cross-section view diagram illustrating the chip package in accordance with the preferred embodiment of the present invention.

### DETAILED DESCRIPTION OF THE INVENTION

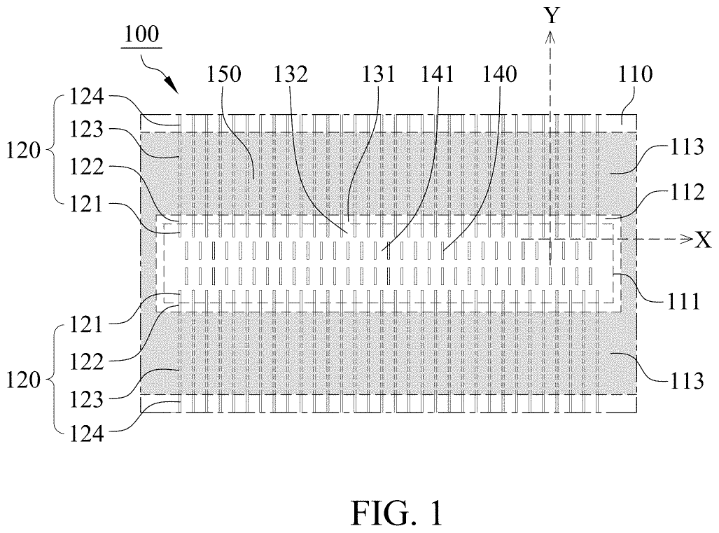

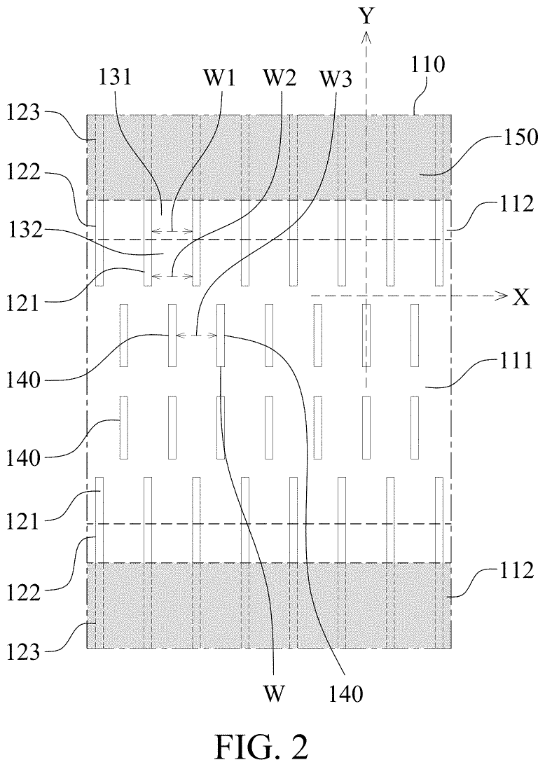

With reference to FIGS. 1 and 2, a circuit board 100 in accordance with a preferred embodiment of the present invention includes a substrate 110, a plurality of first circuit lines 120, a plurality of second circuit lines 140 and a solder resist layer 150. The substrate 110 is, but not limited to, made of polyimide (PI). A chip mounting area 111 and an underfill covering area 112 are defined on the substrate 110, and along a direction of a first axis Y, the underfill covering area 112 is adjacent to the chip mounting area 111. In this embodiment, there is also a layout area 113 defined on the substrate 110, the layout area 113 is adjacent to the underfill covering area 112, and the underfill covering area 112 is located between the chip mounting area 111 and the layout area 113. The solder resist layer 150 covers the layout area 113.

With reference to FIGS. 1 and 2, the first circuit lines 120 are arranged on the substrate 110 along a direction of a second axis X intersecting with the first axis Y and each includes an inner lead 121 and a first line fragment 122 connected with each other. The inner leads 121 and the first line fragments 122 are disposed on the chip mounting area 111 and the underfill covering area 112, respectively. With reference to FIG. 2, a first space 131 exists between the adjacent first line fragments 122 and has a first width W1, preferably, the first width W1 is not less than 5 μm. A second space 132 exists between the adjacent inner leads 121 and communicates with the first space 131, the second space 132 has a second width W2 more than or equal to the first width W1.

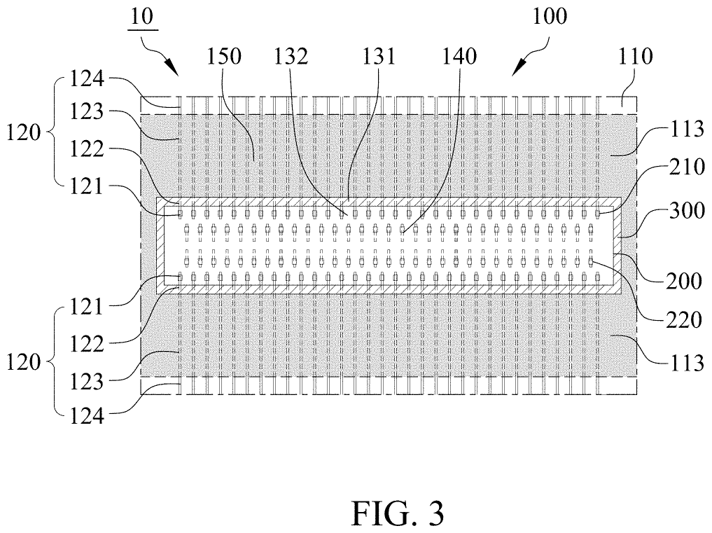

With reference to FIGS. 3 to 5, a chip package 10 in accordance with a preferred embodiment of the present invention includes the circuit board 100, a chip 200 and an underfill 300. The inner leads 121 are provided to bond with first bumps 210 of the chip 200. In this embodiment, each of the first circuit lines 120 further includes a second line fragment 123 and an outer lead 124, the solder resist layer 150 covers the second line fragments 123 disposed on the layout area 113 and exposes (not cover) the outer leads 124 that are provided to bond with an electronic component (not shown). The first line fragment 122 is connected to the second line fragment 123 and located between the inner lead 121 and the second line fragment 123.

With reference to FIGS. 1 and 2, the second circuit lines 140 are disposed on the chip mounting area 111 and not be disposed between the adjacent inner leads 121. In this embodiment, the first axis Y passes through the first space 131 and the second circuit line 140 such that a larger space exists between the first circuit lines 120 and the second circuit lines 140 to allow the underfill 300 to flow between the circuit board 100 and the chip 200. The second circuit lines 140 are provided to connect second bumps 220 of the chip 200 as shown in FIGS. 3 to 5. The first width W1 of the first space 131 is more than or equal to a width W of each of the second circuit lines 140, and preferably, the second width W2 of the second space 132 is also more than or equal to the width W. A third space 141 exists between the adjacent second circuit lines 140 and has a third width W3.

The substrate 110 may expand or contract due to different materials, manufacture temperatures and manufacture time such that the first space 131, the second space 132 and the third space 141 may be changed in width with the expansion or contraction of the substrate 110 into unqualified values. In order to satisfy the specification, the first width W1 of the first space 131, the second width W2 of the second space 132 and the third width W3 of the third space 141 have to be determined according to the following formulas:

W1=A1+R1 & A1=R1×C

W2=A2+R2 & A2=R2×C

W3=A3+R3 & A3=R3×C

where A1, A2 and A3 are a first compensation value, a second compensation value and a third compensation value, respectively, R1, R2 and R3 are a first predetermined value, a second predetermined value and a third predetermined value, respectively, and C is a coefficient not higher than 0.001. The first predetermined value is a width required value of the first space 131, the second predetermined value is a width required value of the second space 132, and the third predetermined value is a width required value of the third space 141.

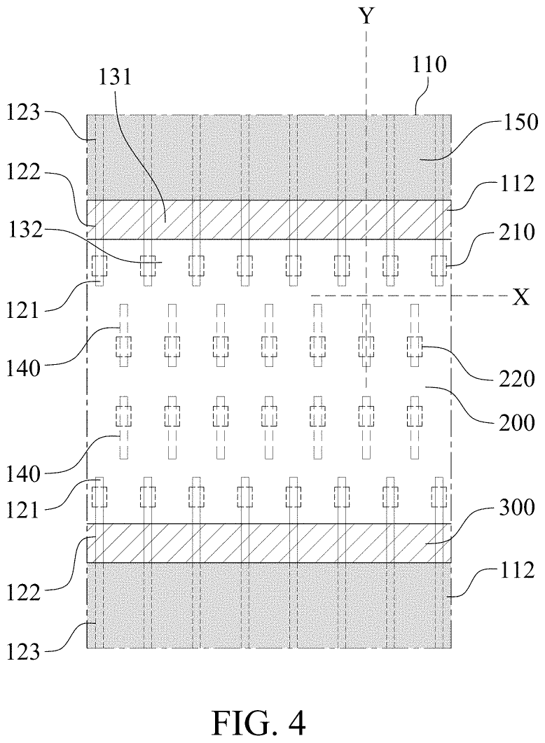

With reference to FIGS. 3 and 4, the substrate 110 is heated to expand or contract during thermal compression bonding, nevertheless, because of space width compensation, the inner leads 121 of the first circuit lines 120 and the second circuit lines 140 are still able to bond with the first bumps 210 and the second bumps 220, respectively. Open circuit or unavailable bonding area caused by shift is preventable.

With reference to FIGS. 1 and 2, the solder resist layer 150 covers the substrate 110 and exposes the chip mounting area 111, the underfill covering area 112, the inner leads 121, the first line fragments 122, the first space 131 and the second circuit lines 140. In this embodiment, the solder resist layer 150 further covers the layout are 113 and the second line fragments 123.

With reference to FIGS. 3 to 5, the chip 200 of the chip package 10 is mounted on the chip mounting area 111 such that the first bumps 210 are bonded to the inner leads 121 and the second bumps 220 are bonded to the second circuit lines 140. In this embodiment, the chip 200 has a length L less than or equal to 42 mm along the direction of the second axis X, and each of the first bumps 210 has a thickness D less than or equal to 18 μm. Preferably, the second bumps 220 have the same thickness as the first bumps 210.

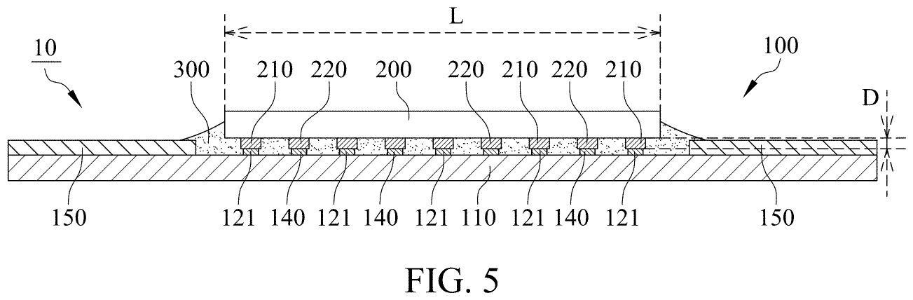

With reference to FIGS. 4 and 5, the underfill 300 is filled between the substrate 110 and the chip 200 and covers the underfill covering area 112 and the first line fragments 122. Preferably, the underfill 300 also covers the inner leads 121, the first bumps 210 and the second bumps 220.

The second circuit lines 140 are disposed on the chip mounting area 111 but not located between the adjacent inner leads 121 so as to form the wider first space 131 between the adjacent first line fragments 122. For this reason, bridge circuit is avoided in circuit forming process and short circuit caused by the connection of the adjacent first bumps 210 or the adjacent first circuit lines 120 is also avoided during thermal compression. Furthermore, the underfill 300 coated on the underfill covering area 112 can flow to between the substrate 110 and the chip 200 via the first space 131 to prevent air bubbles from being embedded between the circuit board 100 and the chip 200.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A circuit board, comprising:
a substrate having a chip mounting area and an underfill covering area, the underfill covering area is adjacent to the chip mounting area along a direction of a first axis;
a plurality of first circuit lines arranged on the substrate along a direction of a second axis intersecting with the first axis, each of the first circuit lines includes an inner lead and a first line fragment connected with each other, a first space having a first width exists between the first line fragment of the adjacent first circuit lines, the inner lead of each of the first circuit lines is disposed on the chip mounting area and configured to bond to a first bump of a chip, and the first line fragment of each of the first circuit lines is disposed on the underfill covering area;
a plurality of second circuit lines disposed on the chip mounting area and not located between the inner lead of the adjacent first circuit lines, each of the second circuit lines is configured to bond to a second bump of the chip and has a width less than or equal to the first width of the first space; and
a solder resist layer covering the substrate and exposing the chip mounting area, the underfill covering area, the inner lead and the first line fragment of each of the first circuit lines, the first space and the second circuit lines.

2. The circuit board in accordance with claim 1, wherein a second space exists between the inner lead of the adjacent first circuit lines, the second space communicates with the first space and has a second width more than or equal to the first width of the first space and the width of each of the second circuit lines.

3. The circuit board in accordance with claim 1, wherein the first width of the first space satisfies a formula as following,
W1=A1+R1 & A1=R1×C
where W1 is the first width, A1 is a first compensation value, R1 is a first predetermined value that is a width required value of the first space, and C is a coefficient less than or equal to 0.001.

4. The circuit board in accordance with claim 2, wherein the second width of the second space satisfies a formula as following,
W2=A2+R2 & A2=R2×C
where W2 is the second width, A2 is a second compensation value, R2 is a second predetermined value that is a width required value of the second space, and C is a coefficient less than or equal to 0.001.

5. The circuit board in accordance with claim 1, wherein a third space exists between the adjacent second circuit lines and has a third width, the third width satisfies a formula as following,
W3=A3+R3 & A3=R3×C
where W3 is the third width, A3 is a third compensation value, R3 is a third predetermined value that is a width required value of the third space, and C is a coefficient less than or equal to 0.001.

6. The circuit board in accordance with claim 1, wherein the first width of the first space is more than or equal to 5 μm.

7. The circuit board in accordance with claim 1, wherein the first axis passes through the first space and the second circuit line.

8. A chip package, comprising:
a circuit board including a substrate, a plurality of first circuit lines, a plurality of second circuit lines and a solder resist layer, a chip mounting area and an underfill covering area are defined on the substrate, the underfill covering area is adjacent to the chip mounting area along a direction of a first axis, the first circuit lines are arranged on the substrate along a direction of a second axis intersecting with the first axis and each includes an inner lead and a first line fragment connected with each other, a first space having a first width exists between the first line fragment of the adjacent first circuit lines, the inner lead and the first line fragment of each of the first circuit lines are disposed on the chip mounting area and the underfill covering area respectively, the second circuit lines are disposed on the chip mounting area and not located between the inner lead of the adjacent first circuit lines, each of the second circuit lines has a width less than or equal to the first width of the first space, the solder resist layer covers the substrate and exposes the chip mounting area, the underfill covering area, the inner lead and the first line fragment of each of the first circuit lines, the first space and the second circuit lines;
a chip disposed on the chip mounting area and including a plurality of first bumps and a plurality of second bumps, each of the first bumps is bonded to the inner lead of each of the first circuit lines, and each of the second bumps is bonded to each of the second circuit lines; and
an underfill filled between the substrate and the chip and covering the underfill covering area and the first line fragment of each of the first circuit lines.

9. The chip package in accordance with claim 8, wherein a second space exists between the inner lead of the adjacent first circuit lines, the second space communicates with the first space and has a second width more than or equal to the first width of the first space and the width of each of the second circuit lines.

10. The chip package in accordance with claim 8, wherein the first width of the first space satisfies a formula as following,
W1=A1+R1 & A1=R1×C
where W1 is the first width, A1 is a first compensation value, R1 is a first predetermined value that is a width required value of the first space, and C is a coefficient less than or equal to 0.001.

11. The chip package in accordance with claim 9, wherein the second width of the second space satisfies a formula as following,
W2=A2+R2 & A2=R2×C
where W2 is the second width, A2 is a second compensation value, R2 is a second predetermined value that is a width required value of the second space, and C is a coefficient less than or equal to 0.001.

12. The chip package in accordance with claim 8, wherein a third space exists between the adjacent second circuit lines and has a third width, the third width satisfies a formula as following,
W3=A3+R3 & A3=R3×C
where W3 is the third width, A3 is a third compensation value, R3 is a third predetermined value that is a width required value of the third space, and C is a coefficient less than or equal to 0.001.

13. The chip package in accordance with claim 8, wherein the first width of the first space is more than or equal to 5 μm.

14. The chip package in accordance with claim 8, wherein the first axis passes through the first space and the second circuit line.

15. The chip package in accordance with claim 8, wherein the chip has a length less than or equal to 42 mm along the direction of the second axis.

16. The chip package in accordance with claim 15, wherein each of the first bumps has a thickness less than or equal to 18 μm.

17. The chip package in accordance with claim 8, wherein each of the first bumps has a thickness less than or equal to 18 μm.
